(19) United States
(12) Patent Application Publication
(10) Pub. No.: US 2026/0223626 A1
(43) Pub. Date: Jul. 30, 2026

(54) PRE-CLEANING DEVICE FOR SEMICONDUCTOR SUBSTRATE AND PRE-CLEANING METHOD USING SAME

(71) Applicant: VIATRON TECHNOLOGIES, INC., Gyeonggi-do (KR)

(72) Inventors: Hyoung June Kim, Seoul (KR); Jae Sung Roh, Gyeonggi-do (KR); Wang Jun Park, Gyeonggi-do (KR); Oh Sung Kwon, Gyeonggi-do (KR); Myeong Hun Han, Gyeonggi-do (KR)

(21) Appl. No.: 19/132,856

(22) PCT Filed: Nov. 30, 2023
(86) PCT No.: PCT/KR2023/019558

§ 371 Date: May 26, 2025

(30) Foreign Application Priority Data
Nov. 30, 2022 (KR) 10-2022-0163689

(51) Int. Cl. H10P 72/00; H10P 14/60; H10P 34/42

(52) U.S. Cl. CPC H10P 72/0436; H10P 14/6529; H10P 34/42

(57) ABSTRACT

The present disclosure discloses a pre-cleaning apparatus including a process chamber having a hollow interior and comprising a process gas supply hole formed in a side upper portion and a lower discharge hole formed in a lower side, a susceptor positioned a lower portion in the process chamber and configured to allow the semiconductor substrate to be placed thereon, a shower head coupled to the process chamber in a horizontal direction between an upper surface of the susceptor and the process gas supply hole, a laser beam transmitting plate coupled horizontally to the process chamber above the process gas supply hole, a substrate heating unit positioned above the laser beam transmitting plate, and a gas supply unit configured to supply a process gas.

### TECHNICAL FIELD

The present disclosure relates to a pre-cleaning apparatus for removing oxides or nitrides present on a surface of a semiconductor substrate, and a pre-cleaning method using this apparatus.

### BACKGROUND ART

A semiconductor substrate, such as a silicon substrate, may have a silicon oxide film on its surface, and the silicon oxide film may interfere with the formation of a required thin film on the surface of the semiconductor substrate. Therefore, it is necessary to pre-clean the silicon oxide film through a pre-cleaning process on the semiconductor substrate before the semiconductor manufacturing process is carried out.

An existing pre-cleaning method for pre-cleaning the silicon oxide film may include a first process for changing the silicon oxide film to ammonium hexafluorosilicate, and a second process for sublimating the changed ammonium hexafluorosilicate. The first process is performed by supplying NF₃ gas in a plasma state, together with a carrier gas, to the surface of the semiconductor substrate being placed on an upper surface of a susceptor. The first process is performed by heating the semiconductor substrate to a first temperature using the susceptor. The second process is performed by heating the semiconductor substrate to a second temperature higher than the first temperature. Thus, the pre-cleaning method may be performed by sequentially heating the semiconductor substrate to the first temperature and the second temperature.

An existing pre-cleaning apparatus for pre-cleaning the silicon oxide film is performed by heating the semiconductor substrate together with the susceptor to the first temperature and the second temperature. Thus, this pre-cleaning apparatus requires time to raise the temperature of the semiconductor substrate from the first temperature to the second temperature, so the overall process time may be increased.

### DISCLOSURE OF THE INVENTION

### Technical Problem

An object of the present disclosure is to provide a pre-cleaning apparatus for a semiconductor substrate and a pre-cleaning method using the same, which can easily control a temperature of the semiconductor substrate in the process of removing oxides or nitrides formed on a surface of the semiconductor substrate.

### Technical Solution

A pre-cleaning apparatus for a semiconductor substrate of the present disclosure is characterized in that a process gas is supplied to a silicon oxide film formed on an upper surface of the semiconductor substrate to convert the silicon oxide film into a sublimable conversion film, and a laser beam emitted from a VCSEL device is irradiated to the conversion film to sublimate and remove the conversion film.

In addition, a pre-cleaning apparatus for a semiconductor substrate of the present disclosure is a pre-cleaning apparatus for pre-cleaning a silicon oxide film formed on an upper surface of the semiconductor substrate, and may include a process chamber having a hollow interior and comprising a process gas supply hole formed in a side upper portion and a lower discharge hole formed in a lower side; a susceptor positioned a lower portion in the process chamber and configured to allow the semiconductor substrate to be placed thereon; a shower head coupled to the process chamber in a horizontal direction between an upper surface of the susceptor and the process gas supply hole, and comprising a head gas hole passing therethrough from the upper surface to a lower surface, and being formed from a transparent material; a laser beam transmitting plate coupled horizontally to the process chamber above the process gas supply hole, and being formed from a transparent material; a substrate heating unit positioned above the laser beam transmitting plate, and irradiating a laser beam to the semiconductor substrate; and a gas supply unit configured to supply a process gas, which reacts with the silicon oxide film to convert it into a sublimable film, to the process gas supply hole.

Also, the pre-cleaning apparatus for the semiconductor substrate may further include an intermediate insulation plate connected to the process chamber in a horizontal direction between the laser beam transmitting plate and the substrate heating unit and being formed from a transparent material.

In addition, the process chamber may include a chamber sidewall formed in the shape of a barrel with a hollow interior and a lower plate coupled to a lower portion of the chamber sidewall, an outer circumferential surface of the susceptor may be spaced apart from an inner circumferential surface of the chamber sidewall, and the lower discharge hole may be formed between the inner circumferential surface of the chamber sidewall and the outer circumferential surface of the susceptor, and passes through the lower plate from an upper surface to a lower surface.

Furthermore, the susceptor may further include an edge ring formed in a ring shape and coupled to an upper portion of the outer circumferential surface of the susceptor, and the edge ring may be coupled to the susceptor such that the outer circumferential surface thereof is spaced apart from the inner circumferential surface of the chamber sidewall by a discharge gas gap.

In addition, the substrate heating unit may include a VCSEL module comprising a device array plate coupled to an inner part of an upper portion of the process chamber and a VCSEL device emitting the laser beam, and the plurality of VCSEL modules may be arranged in a grid shape and placed on a lower surface of the device array plate to irradiate the laser beam to the upper surface of the semiconductor substrate.

In addition, a pre-cleaning method for a semiconductor substrate of the present disclosure may include a semiconductor substrate providing step of placing a semiconductor substrate on which a silicon oxide film is formed to an upper surface of a susceptor disposed within a process chamber; a silicon oxide film converting step of supplying a process gas including NF₃ and NH₃ to an upper surface of the semiconductor substrate to convert the silicon oxide film into a conversion film; and a conversion film sublimating step of irradiating a laser beam to the upper surface of the semiconductor substrate to sublimate the conversion film.

The pre-cleaning method for the semiconductor substrate may further include a sublimation residue removing step of, after the conversion film sublimating step, supplying a process gas including hydrogen to the upper surface of the semiconductor substrate to remove sublimation residue remained on the upper surface of the semiconductor substrate.

### ADVANTAGEOUS EFFECTS

In the pre-cleaning apparatus for a semiconductor substrate and the pre-cleaning method using the same according to the present disclosure, in the process of removing oxides or nitrides formed on a surface of the semiconductor substrate, the semiconductor substrate is heated using the substrate heating unit constituted of the VCSEL device, so it is possible to easily control a temperature of the semiconductor substrate.

Also, in the pre-cleaning apparatus for a semiconductor substrate and the pre-cleaning method using the same according to the present disclosure, the laser beam emitted from the substrate heating unit may be irradiated to an upper surface of the semiconductor substrate to heat the semiconductor substrate, thereby increasing the temperature rise rate of the semiconductor substrate and reducing the process time.

In addition, in the pre-cleaning apparatus for a semiconductor substrate and the pre-cleaning method using the same according to the present disclosure, in a case where the irradiation of the laser beam to the upper surface of the semiconductor substrate is halted, it is possible to increase the cooling rate of the semiconductor substrate and reduce the process time.

Furthermore, in the pre-cleaning apparatus for a semiconductor substrate and the pre-cleaning method using the same according to the present disclosure, since the semiconductor substrate is first heated using the susceptor and is further heated using the laser beam emitted from the substrate heating unit, it is possible to efficiently heat the semiconductor substrate.

### BRIEF DESCRIPTION OF THE DRAWINGS

FIG. 1 is a vertical cross-sectional view of an apparatus for pre-cleaning a semiconductor substrate, according to one embodiment of the present disclosure.

FIG. 2 is a horizontal cross-sectional view taken along the A-A in FIG. 1.

FIG. 3 is a partial enlarged view for the section “B” in FIG. 1.

FIG. 4 is a partial perspective view of a substrate heating unit according to one embodiment of the present disclosure.

FIG. 5 is a partial perspective view of a substrate heating unit according to another embodiment of the present disclosure.

FIG. 6 is a partial perspective view of a substrate heating unit according to yet another embodiment of the present disclosure.

FIG. 7 is a view illustrating a process for a method for pre-cleaning a semiconductor substrate according to one embodiment of the present disclosure.

FIG. 8 is a vertical cross-sectional view illustrating the operation of the pre-cleaning apparatus of FIG. 1 in a silicon oxide film conversion step of FIG. 7.

FIG. 9 is a vertical cross-sectional view illustrating the operation of the pre-cleaning apparatus of FIG. 1 in a conversion film sublimation step of FIG. 7.

### BEST MODE FOR CARRYING OUT THE INVENTION

Hereinafter, an apparatus for pre-cleaning a semiconductor substrate of the present disclosure and a pre-cleaning method using the same are described in more detail with reference to embodiments and the accompanying drawings.

First, an apparatus for pre-cleaning a semiconductor substrate according to one embodiment of the present disclosure is described.

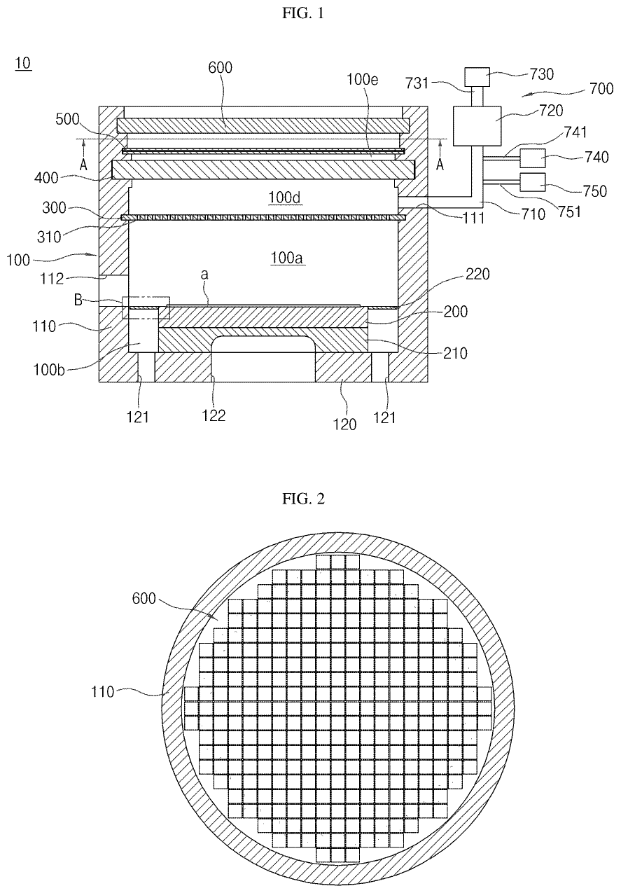

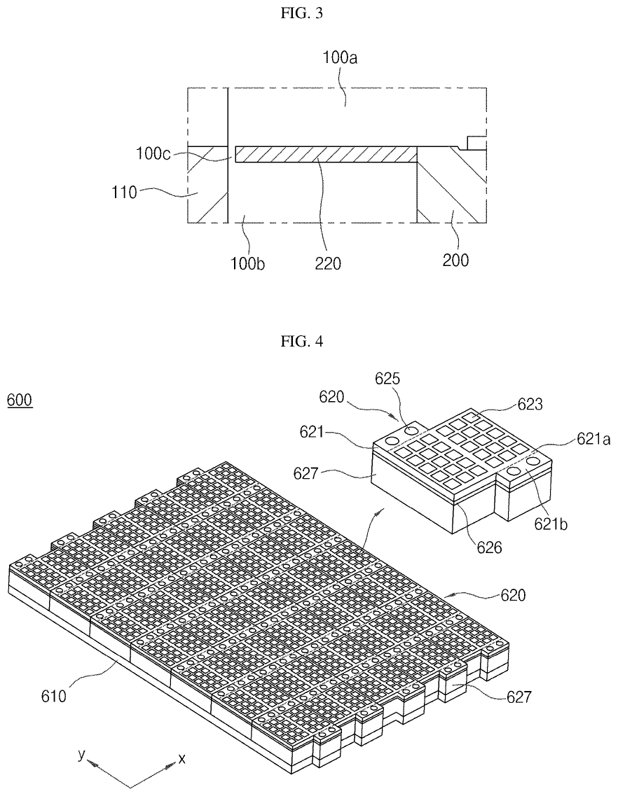

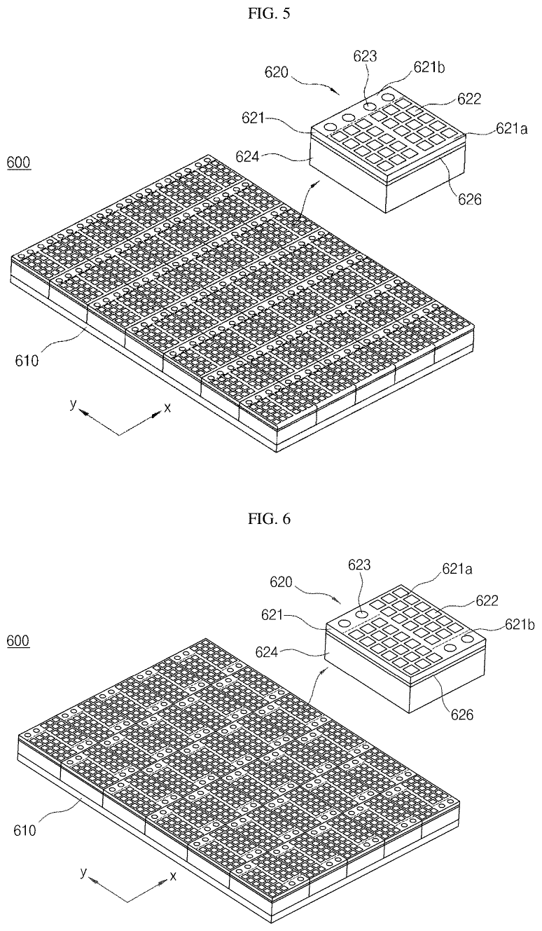

FIG. 1 is a vertical cross-sectional view of an apparatus for pre-cleaning a semiconductor substrate, according to one embodiment of the present disclosure. FIG. 2 is a horizontal cross-sectional view taken along the A-A in FIG. 1. FIG. 3 is a partial enlarged view for the section “B” in FIG. 1. FIG. 4 is a partial perspective view of a substrate heating unit according to one embodiment of the present disclosure. FIG. 5 is a partial perspective view of a substrate heating unit according to another embodiment of the present disclosure. FIG. 6 is a partial perspective view of a substrate heating unit according to yet another embodiment of the present disclosure.

Referring to FIGS. 1 to 4, an apparatus 10 for pre-cleaning a semiconductor substrate, according to one embodiment of the present disclosure may include a process chamber 100, a susceptor 200, a shower head 300, a laser beam transmitting plate 400, a substrate heating unit 600, and a gas supply unit 700. In addition, the pre-cleaning apparatus 10 may further include an intermediate insulation plate 500.

The pre-cleaning apparatus 10 may remove silicon oxides formed on a surface of a semiconductor substrate a such as a silicon substrate. The pre-cleaning apparatus 10 may remove a silicon oxide film formed on an upper surface of the semiconductor substrate a using a conventional process for removing the silicon oxide film. That is, the pre-cleaning apparatus 10 may supply process gas including NF₃ and NH₃ to remove the silicon oxide film. Furthermore, in the pre-cleaning apparatus 10, a silicon nitride film or films of other materials formed on the upper surface of the semiconductor substrate a can be removed by varying the type of process gas supplied from the gas supply unit 700. Therefore, the pre-cleaning apparatus is not limited to a silicon oxide film as an applicable film, and can be applied to various films. Furthermore, the pre-cleaning apparatus 10 may be applied to an etching process for the semiconductor substrate a or to an etching process for films of various materials formed on the upper surface of the semiconductor substrate a in addition to the pre-cleaning process for the semiconductor substrate a.

The pre-cleaning apparatus 10 may irradiate a laser beam from the substrate heating unit 300 positioned above the semiconductor substrate a to an upper portion of the semiconductor substrate a to heat the semiconductor substrate a. Thus, since the pre-cleaning apparatus 10 irradiate the laser beam to the semiconductor substrate a to directly heat the semiconductor substrate a, it is possible to easily control a temperature of the semiconductor substrate a. In other words, the pre-cleaning apparatus 10 may raise a temperature of the semiconductor substrate a in a relatively short time.

Further, the pre-cleaning apparatus 10 may cool the semiconductor substrate a in a relatively short time. Here, the term of “relatively” means comparing the apparatus of the present disclosure to a conventional apparatus in which the semiconductor substrate a is heated by the susceptor 200. The pre-cleaning apparatus 10 may heat the semiconductor substrate a to a temperature of 200° C. or higher. In addition, the pre-cleaning apparatus 10 may heat the semiconductor substrate a to a temperature of 100 to 150° C.

The pre-cleaning apparatus 10 may irradiate a laser beam in the infrared-ray wavelength range from the substrate heating unit 600 to heat the semiconductor substrate a. Further, the pre-cleaning apparatus 10 may irradiate a laser beam of a single wavelength.

For example, the pre-cleaning apparatus 10 may preferably be a device irradiating a laser beam of a single wavelength of approximately 940 nm. Alternatively, the pre-cleaning apparatus 10 may be a device that irradiates laser beams of multiple wavelengths.

The process chamber 100 may include a chamber sidewall 110 and a lower plate 120. In addition, the process chamber 100 may further include an upper plate (not shown) coupled to an upper portion thereof. The process chamber 100 may be formed in the shape of a barrel with a hollow interior. The process chamber 100 may be formed in a roughly cylindrical shape, a square barrel shape, a pentagonal barrel shape, or a hexagonal barrel shape. Further, the process chamber 100 may have an opened upper portion.

The process chamber 100 may have a space formed therein to receive the susceptor 200, the shower head 300, the laser beam transmitting plate 400, and the substrate heating unit 600. Further, the process chamber 100 may provide a process region in which the semiconductor substrate a is received and the pre-cleaning process is performed.

The process chamber 100 may be formed in a shape having a horizontal cross-sectional area larger than an area of the semiconductor substrate a to be received therein. The process chamber 100 may be formed from a metallic material that is resistant to breakage due to pressure and temperature changes, to cope with positive and negative pressure conditions and a rapid temperature change condition encountered during manufacturing. Further, the process chamber 100 may be formed from a metallic material that is corrosion-resistant to process gases used in the manufacturing process. The process chamber 100 may be formed from a metallic material such as stainless steel, an invar alloy, or hastelloy.

The chamber sidewall 110 may include a process gas supply hole 111a and a substrate gate 112. In addition, although not specifically illustrated, the chamber sidewall 110 may include additional holes required to perform the pre-cleaning process.

The chamber sidewall 110 may be formed in the shape of a barrel which is hollow on the inside. The chamber side wall 110 may be formed in a cylindrical shape, a square barrel shape, a pentagonal barrel shape, or a hexagonal barrel shape. The chamber sidewall 110 may provide a space within which the susceptor 200, the shower head 300, the laser beam transmitting plate 400, and the substrate heating unit 600 are received.

The process gas supply hole 111 may be formed in one side of the chamber sidewall 110 and pass through the chamber sidewall from the outside to the inside thereof. The process gas supply hole 111 may be formed in a side upper portion of the process chamber 100. The process gas supply hole may be formed at a location between the shower head 300 and the laser beam transmitting plate. The process gas supply hole 111 may provide a flow passage through which a process gas is supplied to a space above the shower head 300.

The substrate gate 112 may be formed in the other side of the chamber and pass through the chamber from the outside to the inside thereof. The substrate gate 112 may be formed at a height which is equal to or greater than a height of the susceptor 200. The substrate gate 112 may provide a passage through which the semiconductor substrate a to be or being placed on the susceptor 200 for the pre-cleaning process enters or exits together with a transfer robot. Accordingly, the substrate gate 112 may be formed with a width greater than a diameter of the semiconductor substrate a. Further, the substrate gate 112 may be formed with a height greater than a thickness of the semiconductor substrate a and a thickness of the transfer robot.

Additionally, although not specifically illustrated, a gate valve may be coupled to an outer end of the substrate gate 112. During the pre-cleaning process, the gate valve may seal the substrate gate 112 airtight. In addition, during an entry or exit of the semiconductor substrate a, the gate valve may open the substrate gate 112.

The lower plate 120 may include a lower discharge hole 121 and a lower central hole 122. In addition, the lower plate 120 may further include an additional hole, that is not specifically illustrated, required to carry out the pre-cleaning process.

The lower plate 120 may be formed in the shape of a plate corresponding to a planar shape of the chamber sidewall 110. For example, the lower plate 120 may be formed in the shape of a circular plate having a predetermined thickness. The lower plate 120 may be coupled to a lower portion of the chamber sidewall 110.

The lower drain hole 121 may be formed at a location adjacent to an inner circumferential surface of the chamber sidewall 110 and pass through the lower plate 120 from an upper surface to a lower surface. The lower discharge hole 121 may be formed in a lower surface of the process chamber 100. In addition, the lower discharge hole 121 may be formed at a region between the inner circumferential surface of the chamber sidewall 110 and an outer circumferential surface of the susceptor 200, and pass through the lower plate 120 from the upper surface to the lower surface. Thus, the lower discharge hole 121 may be formed with a diameter smaller than a distance between the inner circumferential surface of the chamber sidewall 110 and the outer circumferential surface of the susceptor 200. At least one lower discharge hole 121 is formed, and a plurality of lower discharge holes may be formed to be spaced apart from each other in a circumferential direction of the lower plate 120.

The lower discharge hole 121 may provide a passage through which a discharge gas, which contains a process gas supplied from the outside for the pre-cleaning process and a reaction by-product gas that is sublimated by the pre-cleaning, is discharged.

The lower discharge hole 121 may be connected to a pumping means (not shown) such as a vacuum pump placed outside the process chamber 100. Thus, the lower discharge hole 121 may allow a process gas and the reaction by-products to be discharged to the outside by a suction force of the pumping means.

The lower central hole 122 may be formed at a central region of the lower plate 120 and pass through the lower plate from the upper surface to the lower surface. The lower central hole 122 may be formed with a diameter smaller than that of the susceptor 200. The lower central hole 122 may provide a passage through which an ejector pin (not shown) coupled to the susceptor 200, a cooling water line (not shown) connected to a cooling flow passage of the susceptor 200, a power line (not shown) connected to a capacitive electrode of the susceptor 200, and the like pass.

A susceptor which is used in a conventional semiconductor process apparatus may be employed as the susceptor 200. For example, the susceptor 200 may be formed in the shape of a circular plate having a predetermined thickness. The susceptor 200 may be formed with a diameter greater than that of the semiconductor substrate a. In addition, the susceptor 200 may be provided with a substrate placing recess formed on an upper surface thereof to allow the semiconductor substrate a to be stably placed. The susceptor 200 may have an ejector pin (not shown) extending from a bottom surface of the placing recess to a lower surface of the susceptor 200. In addition, the susceptor 200 may include a cooling water flow passage (not shown) and a capacitive electrode (not shown) disposed therein.

The process chamber 100 may have a process progressing space 100a, in which the pre-cleaning process is carried out, formed above the susceptor 200. The semiconductor substrate a may be placed on the upper surface of the susceptor 200 to expose the upper surface thereof to the process progressing space 100a.

The susceptor 200 may be placed on a central region of an upper portion of the lower plate 120. The susceptor 200 may be spaced apart from and supported on the upper portion of the lower plate 120 by a separate support plate 210. The support plate 210 may be formed with an outer diameter corresponding to an outer diameter of the susceptor 200. In addition, the support plate 210 may be formed with a recess extending upwardly and having a diameter equal to an inner diameter of the lower central hole 122. Furthermore, the support plate 210 may be formed with a hole having an inner diameter equal to or larger than an inner diameter of the lower central hole. The support plate 210 may seal a gap between the lower surface of the susceptor 200 and the upper surface of the lower plate 120 while supporting the susceptor 200. The support plate 210 may be formed from an insulation material. For example, the support plate 210 may be formed from a polyimide material. The support plate 210 may prevent heat from the susceptor 200 from being transferred to the outside through the lower plate 120.

The susceptor 200 may be formed with an outer diameter smaller than an inner diameter of the chamber sidewall 110. An outer circumferential surface of the susceptor 200 may be spaced apart from an inner circumferential surface of the chamber sidewall 110. Between an outer circumferential surface of the susceptor 200 and an inner circumferential surface of the chamber sidewall 110, a discharge gas passage 100b formed in a ring may be formed. The discharge gas passage 100b may provide a passage through which a process gas supplied from the outside and a reaction by-product gas, that is sublimated on the upper surface of the semiconductor substrate a by the pre-cleaning, flow from the process progressing space 100a into the lower discharge hole 121. The discharge gas passage may be formed with a width greater than an inner diameter of the lower discharge hole 121. In addition, the discharge gas passage may be formed with a width that is sufficient to allow the discharge gas to flow.

The susceptor 200 may further include an edge ring 220 coupled to an upper portion of the outer circumferential surface thereof. The edge ring 220 may be formed with an inner diameter which causes an inner circumferential surface thereof to be in contact with the outer circumferential surface of the susceptor 200. In addition, the edge ring 220 may be formed with an outer diameter required to form a discharge gas gap 100c between an outer circumferential surface and the inner circumferential surface of the chamber sidewall. The discharge gas gap may be smaller than a width of the discharge gas passage 100b.

The discharge gas gap 100c may be formed to have a width of 1 to 5 mm. The edge ring 220 may be formed to be integrally coupled with the susceptor 200. For example, the edge ring 220 may be secured and coupled by separate securing means such that the inner circumferential surface thereof comes into contact with the outer circumferential surface of the susceptor 200. In addition, the edge ring 220 may be detachably coupled to the susceptor by being seated on a stepped-jaw formed on an upper portion of an outer part of the susceptor 200.

In addition, the edge 220 may be formed with a thickness less than a thickness of the susceptor 200. The edge ring 220 may be formed with a thickness of 3 to 6 mm. In addition, the edge ring 220 may be formed from a material such as alumina, silicon carbide, or the like. The edge ring 220 may be formed with a thickness as thin as possible, so it can be heated together with semiconductor substrate when the semiconductor substrate is heated. Thus, the edge ring 220 may allow the silicon oxide films formed on the upper surface of the semiconductor substrate a to be sublimated smoothly. In addition, the edge ring 220 may prevent the sublimated and transferred gases from being re-solidified and then adhered again.

The edge ring 220 may be positioned above the discharge gas passage 100b to separate the discharge gas passage 100b present therebelow from the process progressing space 100a present thereabove. In addition, the edge ring 220 may cause the discharge gas passage 100b and the process progressing space 100a to be connected to each other via the discharge gas gap 100c. The edge ring 220 may cause the discharge gas passage 100b to be maintained at a relatively low negative pressure and the process progressing space 100a to be maintained at a relatively high positive pressure during the process of discharging the discharge gas. Thus, the discharge gas can flow more efficiently from the process progressing space 100a into the discharge gas passage 100b and be then discharged to the outside.

The shower head 300 may be provided with a head gas hole 310. The shower head 300 may be formed in the shape of a plate which is the same as a planar shape of the process chamber 100. The shower head 300 may be formed in the shape of a circular plate. The shower head 300 may be formed from a transparent material through which the laser beam is transmitted. In addition, the shower head 300 may be formed from a material that is corrosion resistant to a process gas. The shower head 300 may be formed from a quartz material.

The head gas hole 310 may be formed in the shower head 300 and pass through the shower head from an upper surface to a lower surface. The head gas hole 310 may be formed with an inner diameter required to allow the process gas to pass therethrough. For example, the head gas hole 310 may be formed with an inner diameter of 0.5 to 1.2 mm. A plurality of head gas holes 310 may be positioned to be spaced apart from each other throughout the shower head 300.

The shower head 300 may be positioned above the susceptor 200, that is, below the process gas supply hole 111 at an upper portion of the process progressing space 100a. The shower head 300 may be coupled to the process chamber 100 in a horizontal direction between the upper surface of the susceptor 200 and a lower portion of the process gas supply hole 111. An outer circumferential surface of the shower head 300 may be entirely coupled to the inner circumferential surface of the chamber sidewall 110. The shower head 300 may form a process gas space 100d at an upper portion of the process progressing space 100a together with the laser beam transmitting plate 400. The shower head 300 may spray the process gas onto the upper surface of the semiconductor substrate a.

The laser beam transmitting plate 400 may be formed in the shape of a plate corresponding to a horizontal planar shape of the chamber sidewall 110. The laser beam transmitting plate 400 may be formed in the shape of a circular plate. The laser beam transmitting plate 400 may be formed with an outer diameter equal to or greater than an inner diameter of the chamber sidewall 110. The laser beam transmitting plate 400 may be positioned above the process gas supply hole 111 of the chamber sidewall 110 above the shower head 300. The laser beam transmitting plate 400 may be horizontally coupled to an inner part of the chamber sidewall 110. The laser beam transmitting plate 400 may be coupled to be parallel to the shower head 300.

The laser beam transmitting plate 400 may be formed from a transparent material through which the laser beam is transmitted. For example, the laser beam transmitting plate 400 may be formed from quartz. The laser beam transmitting plate 400 may transmit the laser beam, that is irradiated from the substrate heating unit 600 positioned thereabove, downward.

In addition, the laser beam transmitting plate 400 may seal a region above the process gas supply hole 111 at the chamber sidewall 110. The laser beam transmitting plate 400 may prevent the process gas supplied from the process gas supply hole 111 from flowing upward. In other words, the laser beam transmitting plate 400 may prevent the process gas from flowing to the substrate heating unit 600. The laser beam transmitting plate 400 may prevent heat in the process progressing space 100a from being escaped upward and being lost.

The intermediate insulation plate 500 may be formed in the shape of a plate corresponding to a planar shape of the chamber sidewall 110. For example, the intermediate insulation plate may be formed in the shape of a circular plate. The intermediate insulation plate may be formed with an outer diameter equal to or greater than an inner diameter of the chamber sidewall 110. The intermediate insulation plate may be formed with a thickness less than the laser beam transmitting plate 400.

The intermediate insulation plate may be coupled to the chamber sidewall 110 above the laser beam transmitting plate 400. Thus, the intermediate insulation plate may form an insulation space 100e above the laser beam transmitting plate 400. The insulation space 100e may be filled with air or an inert gas. The intermediate insulation plate may prevent heat in the process progressing space 100a from being escaped through the laser beam transmitting plate 400 to the outside and being lost. In addition, the intermediate insulation plate may prevent heat generated in the process progressing space 100a from being transferred through the laser beam transmitting plate 400 to the substrate heating unit 600.

The intermediate insulation plate may be formed in a structure in which two insulation sheets are spaced apart from each other and an air layer or a gas layer is formed between two sheets. Thus, the intermediate insulation plate may have increased thermal insulation performance.

Further, the intermediate insulation plate may be formed from a transparent material through which the laser beam is transmitted. As with the laser beam transmitting plate 400, for example, the intermediate insulation plate may be formed from quartz. In addition, the intermediate insulation plate may be formed from a transparent material such as glass. The intermediate insulation plate may transmit the laser beam, that is irradiated from the substrate heating unit 600 positioned thereabove, downward.

The substrate heating unit 600 may include a device array plate 610 and VCSEL modules 620. As illustrated in FIG. 5, the substrate heating unit 600 may be formed by arranging the plurality of VCSEL modules 220 on an upper surface of the device array plate 610 in a x-direction and a y-direction.

The substrate heating unit 600 may be positioned at an upper portion of the process chamber 100. That is, the substrate heating unit 600 may be positioned above the laser beam transmitting plate 400. In addition, if an intermediate insulation plate is formed, the substrate heating unit 600 may be positioned above the intermediate insulation plate. The substrate heating unit 600 may be coupled to the inside of the chamber sidewall 110 such that the device array plate is positioned on an upper portion and VCSEL module is positioned on a lower portion. The substrate heating unit 600 may irradiate a laser beam to the upper surface of the semiconductor substrate a through the laser beam transmitting plate 400.

The device array plate 610 may be formed in the shape of a plate having a predetermined area and thickness. The device array plate 610 may be formed with a diameter equal to or greater than an inner diameter of the chamber sidewall 110. The device array plate 610 may be formed with an area corresponding to a horizontal plane of the chamber sidewall 110. The device array plate 610 may be formed from a thermally conductive ceramic material or a metallic material. The device array plate 610 may function to dissipate heat generated by the VCSEL module 620.

The VCSEL module 620 may include a device substrate 621, VCSEL devices 623, an electrode terminal 625 and a cooling block 627. The plurality of the VCSEL modules 620 may be arranged in a grid shape and placed on a lower surface of the device array plate 610. The VCSEL module 620 may irradiate the laser beam, which is emitted from the VCSEL device 623, to the upper surface of the semiconductor substrate a to heat it.

The VCSEL module 620 is formed by arranging the plurality of VCSEL devices 623 on an upper surface of the device substrate 621 in the x-axial direction and the y-axial direction. When the VCSEL modules 620 are arranged in the y-axial direction, the terminal region 621b positioned at the other side of a front end portion of the VCSEL module and the terminal region 621b positioned at the one side of a rear end portion of the adjacent VCSEL module 620 may be positioned adjacent to each other in the x-axial direction. In the VCSEL modules 620, the device regions 621a and the terminal regions 621b may be linearly arranged in the x-axial direction, respectively, and the device regions 621a and the terminal regions 621b may be alternately arranged in the y-axial direction.

The device substrate 621 may be formed from a general substrate used for mounting electronic devices. The device substrate 621 may be divided into the device region 621a on which the plurality of VCSEL devices 623 are mounted and the terminal region 621b on which the terminals are mounted. On the device region 621a, the plurality of VCSEL devices 623 may be arranged and mounted in a grid shape. The terminal region 621b is placed adjacent to the device region 621a and a plurality of terminals may be mounted on this terminal region.

The plurality of VCSEL devices 623 are arranged in the x-axial direction and the y-axial direction on the upper surface of the device substrate 621. The VCSEL device 623 may irradiate a laser beam of a single wavelength of 940 nm. Since the VCSEL device 623 emits a high-powered laser beam, it may effectively heat the semiconductor substrate a.

In the VCSEL device 623, a plurality of micro-emitters may be arranged in the x-axial direction and the y-axial direction. Although not specifically illustrated, the VCSEL device 623 may include a light emitting frame (not shown) for securing the micro-emitters and power lines (not shown) for supplying current to the micro-emitters. The VCSEL device 623 may be configured such that the same current is applied to the whole micro-emitters. In addition, the VCSEL device 623 may be configured such that different powers are applied to the micro-emitters, respectively.

The plurality of electrode terminals 625 may be formed on the terminal region 621b of the device substrate 621. The electrode terminals 625 may include a + terminal and a − terminal, and may be electrically connected to the VCSEL device 623. The electrode terminals 625 may be electrically connected to the VCSEL device 623 in a variety of ways, although not specifically shown. The electrode terminal 625 may supply the current required for driving the VCSEL device 623.

The cooling block 627 may be formed with a planar shape corresponding to a planar shape of the device substrate 621 and a predetermined height. The cooling block 627 may be formed of a thermally conductive ceramic material or metallic material. The cooling block 627 may be coupled to a lower surface of the device substrate 621 by a separate adhesive layer. The cooling block 627 may dissipate downwardly heat generated by the VCSEL device 623 mounted on a surface of the device substrate 621. Accordingly, the cooling block 627 may cool the device substrate 621 and the VCSEL device 623. Reference number 626 which is not described may be an adhesive layer that bonds the device substrate 621 and the cooling block 627 to each other.

In addition, the cooling block 627 may have a cooling flow passage (not shown), through which cooling water flows, formed therein. The cooling flow passage has an inlet and an outlet formed in an lower surface of the cooling block 627, and may be formed in various shape within the cooling block.

In the substrate heating unit 600 of another embodiment, depending on the shape in which the VCSEL devices 623 and the electrode terminals 625 are disposed on an upper surface of the device substrate 621, the VCSEL module 620 may be formed in various shapes.

Referring to FIG. 5, the VCSEL module 620 according to another embodiment of the present disclosure may be formed in square or rectangular shape as a whole. In the VCSEL module 620, the device region 621a is formed in a quadrangular shape having an entire width and a predetermined length, and the terminal region 621b may be formed at an entire front or rear end of the device region 621a. Furthermore, the terminal region 621b may be formed with a length a smaller than that of the device region 621a.

In the substrate heating unit 600, when the VCSEL modules 620 are arranged on the device array plate 610 in the y-axial direction, the terminal region 621b positioned at a front end and the device region 621a of another VCSEL module 620 positioned in front of the VCSEL module may be arranged adjacent to each other.

In such a case of the substrate heating unit 600, the device regions 621a and the terminal regions 621b of the VCSEL modules 620 are sequentially arranged in the x-axial direction, respectively, and the device regions 621a and the terminal regions 621b are alternately arranged in the y-axial direction.

Referring to FIG. 6, furthermore, the VCSEL module 620 according to another embodiment of the present disclosure may be formed in a roughly rectangular shape. In addition, in the VCSEL module 620, the terminal regions 621b may be formed on the other side of a front end portion and one side of a rear end portion of the quadrangular shape, respectively, and have a rectangular shape having a predetermined length and a width corresponding to a half of the entire width of the VCSEL module. That is, the terminal region 621b may be formed to have a width corresponding to a half of the width of the VCSEL module.

The terminal regions 621b may be positioned diagonally to each other in the rectangle. In the VCSEL module 620, a region except for the terminal regions 621b may be formed as the device region 621a.

In addition, one side and the other side of the VCSEL module 620 may be formed in a straight-line shape. A length of the terminal region 621b may be smaller than that of the device region 621a. The terminal regions 621b having the same length may be formed at front and rear sides.

When the VCSEL modules 620 are arranged on the device array plate 610 in the y-axial direction, the terminal region 621b positioned at one side of the front end portion may be positioned adjacent to the device region 621a positioned at one side of a rear end portion of another VCSEL module 620 positioned in front of the VCSEL module. When the VCSEL modules 620 are arranged in the y-axial direction, the terminal region 621b positioned at the other side of the rear end portion may be positioned adjacent to the device region 621a positioned at the other side of the front end portion of another VCSEL module 620 positioned in front of the VCSEL module.

In addition, in the VCSEL modules 620, the device regions 621a and the terminal regions 621b are alternately arranged in the x-axial direction on a region on which the terminal regions 621b are formed with respect to the y-axial direction, and the device regions 621a may be linearly arranged in the x-axial direction on a region on which the terminal region 621b is not formed.

Accordingly, the substrate heating unit 600 includes a region in which the device regions 621a and the terminal regions 621b are alternately arranged in the x-axial direction and a region in which only the device regions 621a are arranged, and the device regions 621a and the terminal regions 621b may be alternately arranged in the y-axial direction.

The gas supply unit 700 may include a main gas supply pipe 710, a remote plasma unit (RPU) 720, a first gas supply source 730, a second gas supply source 740, and a third gas supply source 750. The gas supply unit 700 may supply a process gas, which is required for a pre-cleaning process for the semiconductor substrate a, to the semiconductor substrate a. More specifically, the gas supply unit 700 may supply a process gas to the process gas supply hole 111 of the chamber sidewall 110. The process gas may be a gas that reacts with a silicon oxide film formed on a surface of the semiconductor substrate a to convert it into a sublimable film. The gas supply unit 700 may supply a process gas including NF3 and NH3. The process gas may include a first process gas including NF3 and a second process gas including NH3.

The main gas supply pipe 710 may be formed as a general gas pipe used for supplying a gas. The main gas supply pipe 710 may be connected at one end to the process gas supply hole 111. The main gas supply pipe 710 may supply the process gas supplied from the first gas supply source 730, the second gas supply source 740 and the third gas supply source 750 to the process gas supply hole 111.

The remote plasma unit 720 may convert an inflowing gas into plasma. A conventional apparatus used for converting the gas into plasma may be utilized as the remote plasma unit 720. For example, the remote plasma unit 720 may be an inductively coupled plasma (ICP) apparatus. In addition, the remote plasma unit may be an electron cyclotron resonance (ECR) apparatus or a capacitively coupled plasma (CCP) apparatus. The remote plasma unit 720 may be coupled to the other end of the main gas supply pipe 710. The remote plasma unit 720 may convert inflowing gas into plasma and supply it to the main gas supply pipe 710.

The first gas supply source 730 may be connected to the remote plasma unit (720). The first gas supply source 730 may supply the first process gas to the remote plasma unit 720. The first process gas may be a processing gas constituting a process gas. The first process gas may include NF₃. In addition, the first process gas may further include a gas such as argon (Ar), nitrogen (N₂) gas, or oxygen (O₂) gas. The first gas supply source 730 may be connected to the remote plasma unit 720 by a separate gas supply pipe 731.

The second gas supply source 740 may be directly connected to the main gas supply pipe 710. That is, the second gas supply source 740 may be connected to the main gas supply pipe 710 between the process gas supply hole 111 and the remote plasma unit 720. Therefore, the second gas supply source 740 may supply the second process gas to the main gas supply pipe 710. The second process gas may include NH₃ gas. In addition, the second process gas may further include H₂ gas or H₂O. The second gas supply source 740 may be connected to the main gas supply pipe 710 by a separate gas supply pipe 741. Meanwhile, the second gas supply source 740 may also be connected to the remote plasma unit 720. Therefore, the second gas supply source 740 may supply the second process gas to the remote plasma unit 720 to cause it to react with the first process gas.

The third gas supply source 750 may be directly connected to the main gas supply pipe 710. That is, the third gas supply source 750 may be connected to the main gas supply pipe 710 between the process gas supply hole 111 and the remote plasma unit 720. Therefore, the third gas supply source 750 may supply a third process gas to the main gas supply pipe 710. The third process gas may include an inert gas. The inert gas may be argon (Ar) gas or nitrogen (N₂) gas. The third gas supply source 750 may be connected to the main gas supply pipe 710 by a separate gas supply pipe 751.

The following describes a pre-cleaning method using the pre-cleaning apparatus according to one embodiment of the present disclosure.

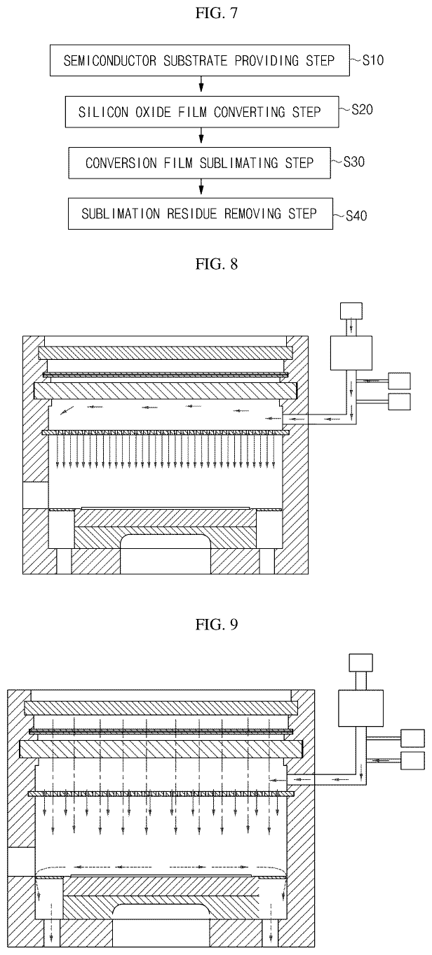

FIG. 7 is a view illustrating a process for a method for pre-cleaning the semiconductor substrate according to one embodiment of the present disclosure. FIG. 8 is a vertical cross-sectional view illustrating the operation of the pre-cleaning apparatus of FIG. 1 in a silicon oxide film conversion step of FIG. 7. FIG. 9 is a vertical cross-sectional view illustrating the operation of the pre-cleaning apparatus of FIG. 1 in a conversion film sublimation step of FIG. 7.

Referring to FIG. 7, a cleaning method using the pre-cleaning apparatus according to one embodiment of the present disclosure may include a semiconductor substrate providing step S10, a silicon oxide film converting step S20, and a conversion film sublimating step S30. The pre-cleaning method may further include a sublimation residue removing step S40. Here, the pre-cleaning method is described with reference to a case where the silicon oxide film is formed on a surface of the semiconductor substrate. However, the pre-cleaning method may be equally applicable to the case where other thin films, such as silicon nitride films, are formed. In such cases, the process gas used in the pre-cleaning method may be different.

The semiconductor substrate providing step S10 is a step of placing the semiconductor substrate on the upper surface of the susceptor 200 disposed within the process chamber 100. The semiconductor substrate a is in a state in which a silicon oxide film is formed on its surface.

The silicon oxide film converting step S20 is a step of converting the silicon oxide film formed on the upper surface of the semiconductor substrate to form a conversion film. In the silicon oxide film converting step S20, the semiconductor substrate a may be heated to a conversion temperature. The conversion temperature may be set in a range of 20 to 60° C. Preferably, the conversion temperature may be set in the range of 30 to 40° C. In the silicon oxide film converting step S20, the semiconductor substrate a may be heated by heating means embedded in the susceptor 200. In addition, in the silicon oxide film converting step S20, by irradiating the laser beam from the substrate heating unit 600, the semiconductor substrate a may be heated.

In the silicon oxide film converting step S20, the process gas including NF₃ and NH₃ may be supplied. More specifically, in the silicon oxide film converting step S20, a first process gas including NF₃ and a second process gas including NH₃ may be supplied to the upper surface of the semiconductor substrate a. The second process gas may further include H₂ or H₂O. The first process gas may pass through the remote plasma unit 720 and then be supplied in a plasma state. The first process gas passes through the remote plasma unit 720 and flows into the process gas supply hole 111 through the main gas supply pipe 710. The second process gas flows into the process gas supply hole 111 through the main gas supply pipe 710. The first process gas and the second process gas are mixed with each other in the process gas space 100d and then sprayed onto the upper surface of the semiconductor substrate a via the shower head 300. The first process gas and the second process gas may react with the silicon oxide formed on the upper surface of the semiconductor substrate a according to the following reaction formula to convert the silicon oxide into a conversion film such as ammonium hexafluorosilicate.

2NH₄F(g)+4HF(g)+SiO₂=(NH₄)₂SiF₆(s)+2H₂O

Since the first process gas flows into the process gas space 100d in a plasma state, NF₃ and NH₃ may react in the process of mixing the first process with the second process gas and be first converted into NH₄F(g) gas. Further, the silicon oxide film converting step S20 may be proceeded by irradiating the laser beam from the substrate heating unit 120 to heat the semiconductor substrate a to a conversion temperature.

The conversion film sublimating step S30 is a step of heating the conversion film to a sublimation temperature to sublimate it. In the conversion film sublimating step S30, the laser beam emitted from the VCSEL module of the substrate heating unit 600 may be irradiated to the upper surface of the semiconductor substrate a to heat the semiconductor substrate a. The conversion temperature may be set in the range of 100 to 300° C. The conversion temperature may be set in the range of 100 to 150° C. In addition, the conversion temperature may be set in the range of 200 to 300° C.

Ammonium hexafluorosilicate, that is the conversion film, may be sublimated according to the following reaction formula.

(NH₄)₂SiF₆(g)=SiF₄(g)+2NH₃(g)+2HF(g)

In the conversion film sublimating step S30, the discharge gas including the gas generated when the conversion film is sublimated may be discharged from the semiconductor substrate a. The conversion film sublimating step S30 may be performed by supplying the third process gas including an inert gas. Therefore, the discharge gas may be a mixture of the gas generated when the conversion film is sublimated and the third process gas. The conversion film sublimating step S30 may be performed by operating an exhaust means connected to the lower discharge hole 121 to discharge the discharge gas. Therefore, the discharge gas may pass through the discharge gas gap 100c and the discharge gas passage 100b, which are formed at the outside of the susceptor 200, and be discharged to the lower discharge hole 121. The discharge gas gap 100c may increase the pressure difference between the process progressing space 100a and the discharge gas passage 100b and increase the rate at which the discharge gas is discharged from the process progressing space 100a.

The sublimation residue removing step S40 is a step of removing sublimation residue remained on the upper surface of the semiconductor substrate by supplying the second process gas including hydrogen to the upper surface of the semiconductor substrate. The sublimation residue may be a material including fluorine (F) remained on the upper surface of the semiconductor substrate a during the sublimation of the conversion film. The sublimation residue removing step S40 may be performed while heating the semiconductor substrate a to a removal temperature. The removal temperature may be set in the range of 150 to 300° C. The sublimation residue removing step S40 may be performed by irradiating the laser beam emitted from the substrate heating unit 600 to the upper surface of the semiconductor substrate a.

In order to help those skilled in the art to understand, the embodiments disclosed herein are the most preferred embodiments selected from the various implementable embodiments, and are set forth in the present specification. In addition, the technical spirit of the present disclosure is not necessarily restricted or limited only by these embodiments, and various changes, additions, and modification are possible without departing from the technical spirit of the present disclosure, and implementations of other equivalent embodiments are possible.

spirit of the present disclosure, and implementations of other equivalent embodiments are possible.

1. A pre-cleaning apparatus for a semiconductor substrate, characterized in that:
a process gas is supplied to a silicon oxide film formed on an upper surface of the semiconductor substrate to convert the silicon oxide film into a sublimable conversion film; and
a laser beam emitted from a VCSEL device is irradiated to the conversion film to sublimate and remove the conversion film.

2. A pre-cleaning apparatus for pre-cleaning a silicon oxide film formed on an upper surface of a semiconductor substrate, comprising:
a process chamber having a hollow interior and comprising a process gas supply hole formed in a side upper portion and a lower discharge hole formed in a lower side;
a susceptor positioned a lower portion in the process chamber and configured to allow the semiconductor substrate to be placed thereon;
a shower head coupled to the process chamber in a horizontal direction between an upper surface of the susceptor and the process gas supply hole, and comprising a head gas hole passing therethrough from the upper surface to a lower surface, and being formed from a transparent material;
a laser beam transmitting plate coupled horizontally to the process chamber above the process gas supply hole, and being formed from a transparent material;
a substrate heating unit positioned above the laser beam transmitting plate, and irradiating a laser beam to the semiconductor substrate; and
a gas supply unit configured to supply a process gas, which reacts with the silicon oxide film to convert it into a sublimable film, to the process gas supply hole.

3. The pre-cleaning apparatus for the semiconductor substrate of claim 2, further comprising an intermediate insulation plate connected to the process chamber in a horizontal direction between the laser beam transmitting plate and the substrate heating unit and being formed from a transparent material.

4. The pre-cleaning apparatus for the semiconductor substrate of claim 2,
wherein the process chamber comprises a chamber sidewall formed in the shape of a barrel with a hollow interior, and a lower plate coupled to a lower portion of the chamber sidewall,
wherein an outer circumferential surface of the susceptor is spaced apart from an inner circumferential surface of the chamber sidewall,
wherein the lower discharge hole is formed between the inner circumferential surface of the chamber sidewall and the outer circumferential surface of the susceptor, and passes through the lower plate from an upper surface to a lower surface.

5. The pre-cleaning apparatus for the semiconductor substrate of claim 4,
wherein the susceptor further comprises an edge ring formed in a ring shape and coupled to an upper portion of the outer circumferential surface of the susceptor,
wherein the edge ring is coupled to the susceptor such that the outer circumferential surface thereof is spaced apart from the inner circumferential surface of the chamber sidewall by a discharge gas gap.

6. The pre-cleaning apparatus for the semiconductor substrate of claim 2, wherein the substrate heating unit comprises a VCSEL module comprising a device array plate coupled to an inner part of an upper portion of the process chamber and a VCSEL device emitting the laser beam, and the plurality of VCSEL modules are arranged in a grid shape and placed on a lower surface of the device array plate to irradiate the laser beam to the upper surface of the semiconductor substrate.

7. A pre-cleaning method for a semiconductor substrate, comprising:
a semiconductor substrate providing step of placing a semiconductor substrate on which a silicon oxide film is formed to an upper surface of a susceptor disposed within a process chamber;
a silicon oxide film converting step of supplying a process gas including NF₃ and NH₃ to an upper surface of the semiconductor substrate to convert the silicon oxide film into a conversion film; and
a conversion film sublimating step of irradiating a laser beam to the upper surface of the semiconductor substrate to sublimate the conversion film.

8. The pre-cleaning method for the semiconductor substrate of claim 7, further comprising a sublimation residue removing step of, after the conversion film sublimating step, supplying a process gas including hydrogen to the upper surface of the semiconductor substrate to remove sublimation residue remained on the upper surface of the semiconductor substrate.
